(19) United States
(12) Patent Application Publication
(10) Pub. No.: US 2009/0159982 A1
(43) Pub. Date: Jun. 25, 2009

(54) Bi-CMOS Semiconductor Device and Method of Manufacturing the Same

(76) Inventor: Yeo Cho YOON, Yeongdeungpo-gu (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/244,787

(22) Filed: Oct. 3, 2008

(30) Foreign Application Priority Data
Dec. 22, 2007 (KR) 10-2007-0135958

(51) Int. Cl. H01L 27/06; H01L 21/8238

(52) U.S. Cl. 257/370; 438/202; 257/E27.015

(57) ABSTRACT

A Bi-CMOS semiconductor device and method for manufacturing the same are provided. An n-well can be formed in a semiconductor substrate, and an NMOS transistor can be provided on the substrate separated from the n-well by a device isolation layer. An NPN bipolar transistor can be formed using the n-well. In particular, a collector contact region and a p-base region can be provided in the n-well. In addition, a base contact region and an emitter contact region can be disposed in the p-base region. A silicide is provided on the source and drain regions and the gate of the NMOS transistor, and the base contact region of the NPN bipolar transistor.

### CROSS-REFERENCE TO RELATED APPLICATION

The present application claims the benefit under 35 U.S.C. §119 of Korean Patent Application No. 10-2007-0135958, filed Dec. 22, 2007, which is hereby incorporated by reference in its entirety.

### BACKGROUND

In general, a bipolar transistor of semiconductor integrated devices has two PN junctions arranged according to a base, a collector, and an emitter on a silicon substrate. A bipolar transistor generally performs switching and amplifying.

In the structure of the bipolar transistor, the collector typically surrounds the emitter region, and a current flows from the emitter to the collector through the base. Also, a current that flows from the emitter to the collector can be controlled by selectively changing a resistance of the base, which is doped in a polarity different from that of the emitter and the collector.

### BRIEF SUMMARY

Embodiments of the present invention provide a Bi-CMOS semiconductor device and method of manufacturing the same.

In one embodiment, a Bi-CMOS semiconductor device can include: a semiconductor substrate including an n-well; an N-channel metal oxide semiconductor (NMOS) transistor on the semiconductor substrate separated from the n-well by a device isolation layer; a p-base region in the n-well; a base contact region and an emitter contact region in the p-base region; a collector contact region in the n-well; and a silicide on a gate, a source and a drain region of the NMOS transistor, and on the base contact region. The source and drain regions, the emitter contact region, and the collector contact region can be formed of n-type ions, and the base contact region and the p-base region can be formed of p-type ions.

The details of one or more embodiments are set forth in the accompanying drawings and the description below. Other features will be apparent from the description and drawings, and from the claims.

### BRIEF DESCRIPTION OF THE DRAWINGS

FIGS. 1 to 8 are cross-sectional views illustrating a method of manufacturing a semiconductor device according to an embodiment of the present invention.

### DETAILED DESCRIPTION

Hereinafter, a semiconductor device and a method of manufacturing the same will be described in detail with reference to the accompanying drawings.

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

FIG. 8 is a cross-sectional view of a semiconductor device according to an embodiment.

Referring to FIG. 8, the semiconductor device can include a MOS transistor structure and a bipolar transistor structure on a semiconductor substrate 10. An n-well 20 and a device isolation layer 5 can be provided in the semiconductor substrate 10. The MOS transistor can be an NMOS transistor 35 including a gate 15 and source and drain regions 30 on the semiconductor substrate 10. The bipolar transistor can include a base contact region 40, an emitter contact region 50, and a collector contact region 60 in the n-well 20. The base contact region 40 and the emitter contact region 50 can be disposed in a p-base region 70 in the n-well 20. A silicide 75 can be formed on the source and drain regions 30 and the gate 15 of the NMOS transistor and on the base contact region 40 of the bipolar transistor. In an embodiment, an interlayer dielectric 80 including contacts 85 can be formed on the semiconductor substrate 10 including the NMOS transistor 35 and the NPN bipolar transistor 100. The contacts 85 can be respectively connected to the source and drain regions 30, the base contact region 40, the emitter contact region 50, and the collector contact region 60. A contact (not shown) can also be connected to the gate 15 of NMOS transistor.

The semiconductor substrate 10 can be, for example, a p-type silicon substrate, and may include an epitaxial layer (not shown).

Also, a thermal oxide layer 2 can be formed between the device isolation layer 5 and the semiconductor substrate 10.

The thermal oxide layer 2 improves the interface characteristics between the semiconductor substrate 10 and a dielectric material that may form the device isolation layer 5.

The p-base region 70 is disposed in the n-well 20. The base contact region 40 and the emitter contact region 50 can be disposed in the p-base region 70.

In an embodiment, the source and drain regions 30, the emitter contact region 50, and the collector contact region 60 can be formed with n-type ions, and the base contact region 40 and the p-base region 70 can be formed with p-type ions.

The emitter contact region 50, the p-base region 70, and the n-well 20 provide the NPN bipolar transistor 100.

The p-base region 70 can be lightly doped with p-type impurities, and the base contact region 40 can be more heavily doped with p-type impurities than the p-base region 70.

Because silicide 75 is formed in the base contact region 40, a contact resistance and a surface resistance of the base contact region 40 can be reduced, thereby forming a device having high frequency characteristics (ft).

In addition, by forming silicide 75 on the base contact region 40, a short circuit can be inhibited from occurring between the base contact region 40 and the emitter contact region 50.

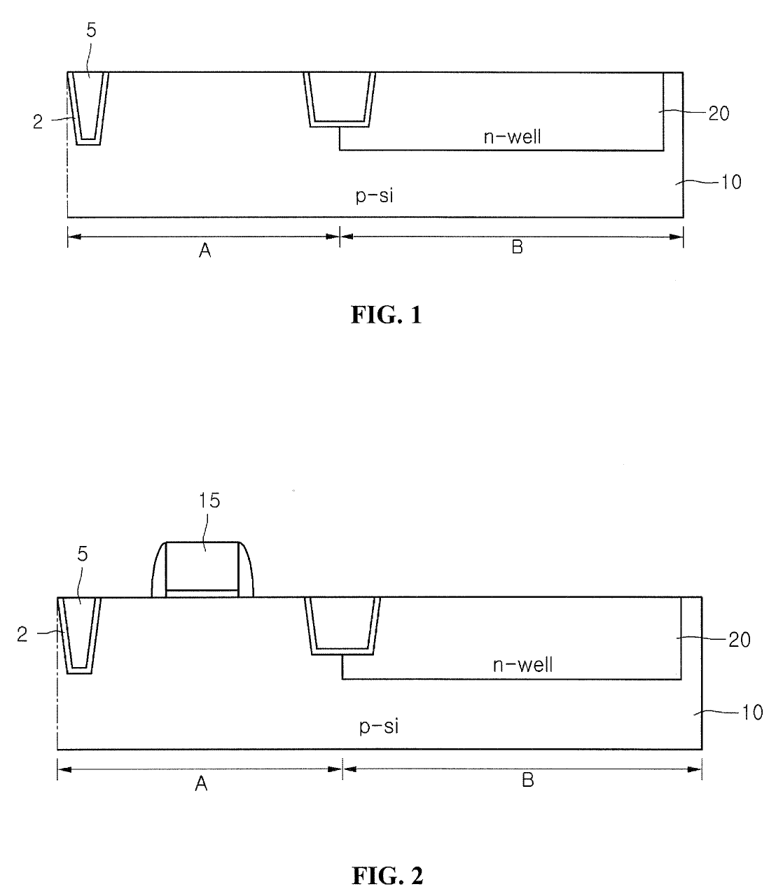

A method of manufacturing a semiconductor device according to an embodiment will be described with reference to FIGS. 1 to 8.

Referring to FIG. 1, an n-well 20 and a device isolation layer 5 can be formed in a semiconductor substrate 10. In an embodiment, the device isolation layer 5 can be formed in the semiconductor substrate 10 separating a first area A from a second area B.

The n-well 20 can be formed in the second area B of the semiconductor substrate 10. The n-well 20 can be formed through any suitable process known in the art. For example, a first photoresist pattern can be formed on the first area A, and a first ion implantation process can be performed to form the n-well 20. Here, an n-type dopant such as phosphorous (P) can be used.

According to the present description, an NMOS transistor will be formed in the first area A and an NPN bipolar transistor will be formed in the second area B.

The semiconductor substrate 10 can be, for example, a p-type substrate, and may include an epitaxial layer (not shown).

A first heat treatment process can be performed on the semiconductor substrate 10 including the n-well 20 so as to activate the ions implanted into the n-well 20.

During the first heat treatment process, the ions implanted into the n-well 20 can be activated and damages of the semiconductor substrate 10 caused by the first ion implantation process can be repaired.

In one embodiment, the device isolation layer 5 can be formed by forming a trench in the semiconductor substrate 10. A thermal oxide layer 2 can be formed in the trench, and then the trench can be filled with a dielectric material.

The thermal oxide layer 2 improves the interface characteristics between the semiconductor substrate 10 and the dielectric material. However, in certain embodiments, the thermal oxide layer 2 may be omitted.

Referring to FIG. 2, a gate 15 can be formed on the semiconductor substrate 10 in the first area A.

The gate 15 can be formed through any suitable process known in the art. For example, the gate can include a first oxide pattern, a polysilicon pattern, and a spacer. According to an embodiment, a first oxide layer and a polysilicon layer can be formed on the semiconductor substrate 10 and patterned to form the first oxide pattern and the polysilicon pattern, respectively. In one embodiment, the spacer can be an oxide-nitride-oxide (ONO) spacer. For example, an ONO layer can be formed on the semiconductor substrate 10 including the first oxide pattern and the polysilicon pattern, and an anisotropic etching process can be performed on the ONO layer so as to form the spacer.

Embodiments of the spacer are not limited to the ONO structure. For example, the spacer can have an oxide-nitride (ON) structure of a second oxide layer and a nitride layer.

Although not shown, before the spacer is formed, a lightly doped drain (LDD) region can be formed in the semiconductor substrate 10 to inhibit leakage of channel current.

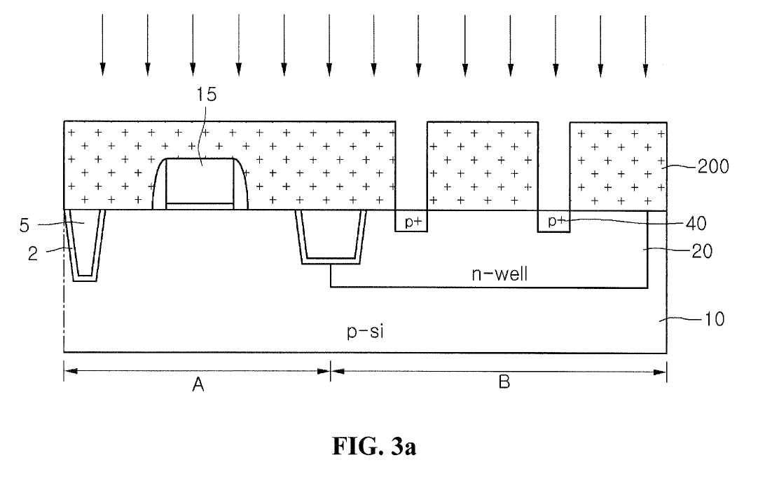

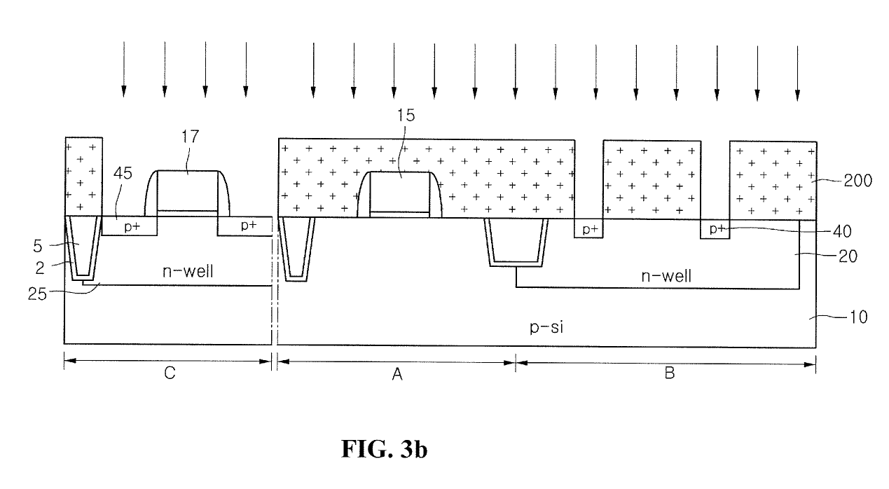

Referring to FIG. 3A, a second photoresist pattern 200 can be formed on the semiconductor substrate 10, and then a second ion implantation process can be performed to form a base contact region 40.

The base contact region 40 can be doped with p-type impurities.

The second ion implantation process can be performed using p-type impurity, such as boron (B).

The base contact region 40 can be formed in the n-well 20 in the second area B.

Referring to FIG. 3B, in one embodiment, the base contact region 40 can be formed simultaneously with source and drain regions 45 of a P-channel metal oxide semiconductor (PMOS) gate 17 on a third area C (not shown). Therefore, an additional mask is not needed during the second ion implantation process when fabricated CMOS transistors.

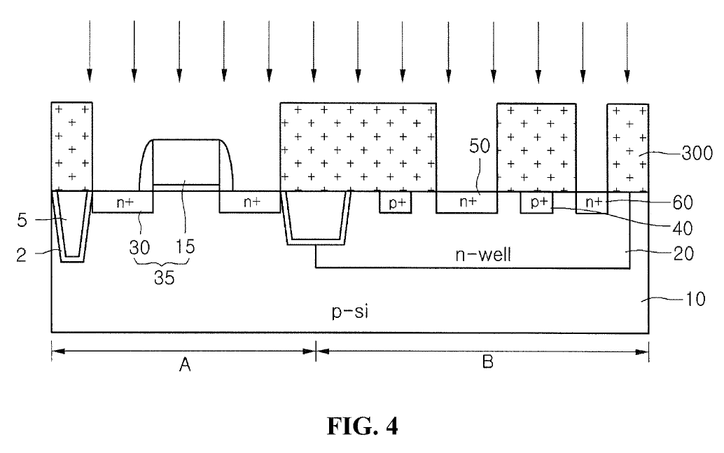

Referring to FIG. 4, a third photoresist pattern 300 can be formed on the semiconductor substrate 10, and then a third ion implantation process can be performed to form an emitter contact region 50 and a collector contact region 60 in the second area B, and source/drain regions 30 in the first area A.

In an embodiment, the emitter contact region 50 and the collector contact region 60 can be formed simultaneously with the source/drain regions 30 during the third ion implantation process. Therefore, an additional mask is not needed during the third ion implantation process.

The third ion implantation process can be performed using n-type impurities such as a phosphorous (P).

Accordingly, an NMOS transistor 35 including the gate 15 and the source/drain regions 30 can be formed.

In addition, through the third implant, the emitter contact region 50 and the collector contact region 60 can be formed in the n-well 20 in the second area B.

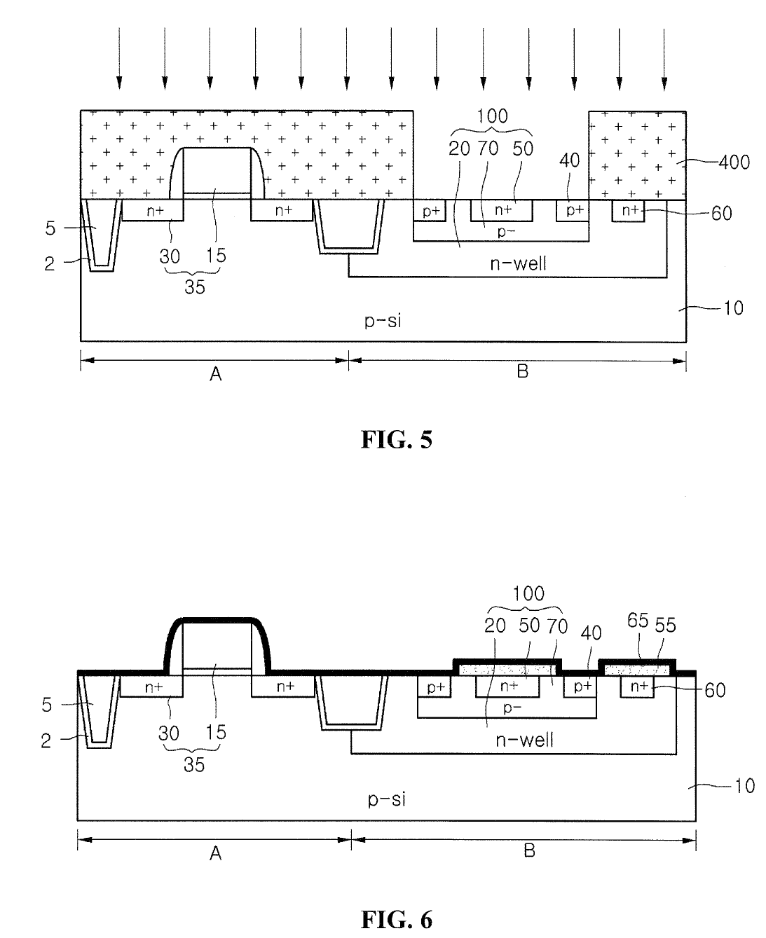

Referring to FIG. 5, a fourth photoresist pattern 400 can be formed on the semiconductor substrate 10, and then a fourth ion implantation process can be performed to form a p-base region 70 in the n-well 20.

The p-base region 70 can be formed using a p-type impurity, such as boron (B), during the fourth ion implantation process. The p-base region 70 can be lightly doped to a shallow depth so as to enhance current gain.

By lightly doping the p-base region 70, current gain can be enhanced.

The p-base region 70 can be formed shallower than the n-well 20. In addition, the p-base region 70 can be formed deeper than the emitter contact region 50 and the base contact region 40.

Therefore, the p-base region 70 is disposed between the emitter contact region 50 and the n-well 20.

In one embodiment, the p-base region 70 can be formed simultaneously with an electro static discharge (ESD) forming process for protecting a device against static electricity in a CMOS transistor forming process. Thus, an additional mask is not needed during the fourth ion implantation process.

According to embodiments of the present invention, an NPN bipolar transistor 100 can be formed of the emitter contact region 50, the p-base region 70, and the n-well 20.

Since the NPN bipolar transistor 100 includes the p-base region 70, current gain (HFE) can be enhanced compared with the PNP bipolar transistor.

Also, the NPN bipolar transistor 100 has a low noise characteristic because electrons, which are majority carriers of the NPN bipolar transistor 100, have excellent mobility compared with holes, which are majority carriers of the PNP bipolar transistor.

Further, the NPN bipolar transistor 100 has a low flicker noise characteristic, and thus may be used for a device requiring a low phase noise characteristic for a voltage controlled oscillator (VCO) circuit.

Referring to FIG. 6, an oxide pattern 55 and a metal layer 65 can be formed on the semiconductor substrate 10.

In one embodiment, the oxide pattern 55 can be formed by forming an oxide layer on the semiconductor substrate 10, and performing a photolithography process and an etching process using a non-salicide mask.

The non-salicide mask is used to create protected regions when a silicide process is to be performed on the source and drain regions 30 and the gate 15 to form a silicide in a CMOS forming process. Here, the oxide pattern 55 can be used to protect the emitter contact region 50 and the collector contact region 60.

In certain embodiments, the oxide pattern 55 can be formed of tetraethyl orthosilicate (TEOS).

Then, the metal layer 65 can be formed on the semiconductor substrate 10 including the oxide pattern 55. The metal layer 65 can be a metal material for forming a silicide, for example, cobalt (Co).

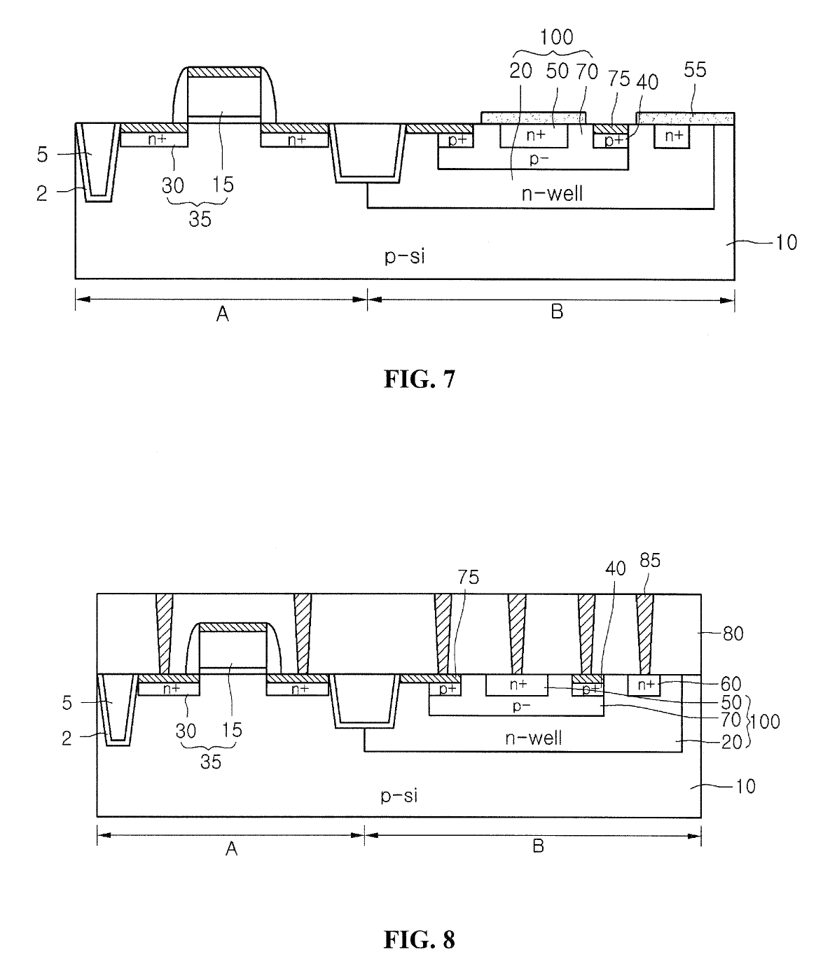

Referring to FIG. 7, a second heat treatment process can be performed to form a silicide 75 in the source and drain regions 30, the gate 15, and the base contact region 40, and remaining unreacted metal of the metal layer 65 can be removed.

During the second heat treatment process for forming the silicide, the source and drain region 30, the base contact region 40, the emitter contact region 50, and the collector contact region 60 are activated.

Because the silicide 75 is formed in the base contact region 40, a contact resistance and a surface resistance of the base contact region 40 can be reduced, thereby providing a device having a high frequency characteristic (ft).

Also, as the silicide 75 is formed in the base contact region 40, a short circuit can be inhibited from occurring between the base contact region 40 and the emitter contact region 50.

Referring to FIG. 8, an interlayer dielectric 80 including contacts 85 can be formed on the semiconductor substrate 10 including the NMOS transistor 35 and the NPN bipolar transistor 100.

The interlayer dielectric 80 can be formed on the semiconductor substrate 10 including the NMOS transistor 35 and the NPN bipolar transistor 100, and then the contacts 85 can be formed in the interlayer dielectric 80 such that the contacts 85 are respectively connected to the source and drain regions 30, the gate electrode (contact not shown) the base contact region 40, the emitter contact region 50, and the collector contact region 60.

The contacts 85 can be formed by forming a contact hole in the interlayer dielectric 80 and filling the contact hole with a metal material such as tungsten (W) or the like.

Although not shown in the drawings, a metal interconnection layer can be formed on the interlayer dielectric 80 including the contacts 85.

In the semiconductor device and the method of manufacturing the same according to embodiments of the present invention, the semiconductor including an NMOS transistor and an NPN bipolar transistor can be formed. An n-well, p-base contact region, base contact, emitter contact, and collector contact can be formed on the p-type semiconductor substrate with the NMOS transistor.

In an embodiment, the source and drain of a PMOS transistor can be formed simultaneously with the base contact region, so that an additional mask is not needed during the ion implantation process.

Also, according to certain embodiments, the emitter contact region and the collector contact region can be formed simultaneously with the source/drain regions of the NMOS transistor, so that an additional mask is not needed during the ion implantation process.

Also, since the p-base contact region can be formed simultaneously with the electro static discharge (ESD) process for protecting a device against static electricity of the CMOS transistor, an additional mask is not needed during such an ion implantation process.

Moreover, the p-base contact region can be lightly doped, thereby enhancing current gain.

Additionally, by forming a bipolar transistor having a low flicker noise characteristic, a low phase noise characteristic can be achieved, so that the semiconductor device having the bipolar transistor can be used for a device of a voltage controlled oscillator (VCO) circuit.

Because silicide is formed in the base contact region, a surface resistance of the base contact region can be reduced, making it possible to provide a device having high frequency characteristics (ft).

Also, a short circuit can be inhibited from occurring between the base contact region and the emitter contact region by forming silicide on the base contact region.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a semiconductor substrate comprising an n-well;
an NMOS transistor on the semiconductor substrate and separated from the n-well by a device isolation layer, the NMOS transistor comprising a gate, and a source region and a drain region;
a p-base region in the n-well;
a base contact region and an emitter contact region in the p-base region;
a collector contact region in the n-well; and
a silicide on the source region, the drain region, the gate, and the base contact region,
wherein the source and drain regions, the emitter contact region, and the collector contact region comprise n-type ions, and the base contact region and the p-base region comprise p-type ions.

2. The semiconductor device according to claim 1, wherein the p-base region comprises the p-type at a low concentration.

3. The semiconductor device according to claim 1, wherein the p-base region is disposed between the emitter contact region and the n-well.

4. The semiconductor device according to claim 1, wherein the p-base region has a depth deeper than that of the emitter contact region and the base contact region.

5. The semiconductor device according to claim 4, wherein the p-base region has a depth shallower than that of the n-well.

6. The semiconductor device according to claim 1, wherein the emitter contact region is in electrical contact with the p-base region and the n-well to form an NPN bipolar transistor.

7. The semiconductor device according to claim 6, further comprising:
a dielectric on the semiconductor substrate, and
contacts formed through the dielectric to contact the silicided source region, the silicided drain region, the silicided gate, the silicided base contact region, the emitter contact region, and the collector contact region, respectively.

8. The semiconductor device according to claim 1, wherein a concentration of the p-type ions of the base contact region is higher than a concentration of the p-type ions of the p-base region.

9. The semiconductor device according to claim 1, further comprising a PMOS transistor on the semiconductor substrate.

10. A method of manufacturing a semiconductor device comprising:
forming an n-well region in a semiconductor substrate;
forming a device isolation layer in the semiconductor substrate;
forming a gate on the semiconductor substrate in a region separated from the n-well by the device isolation layer;
forming a p-type base contact region in the n-well region;
forming n-type source and drain regions for the gate in the semiconductor substrate;
forming an n-type emitter contact region and an n-type collector contact region in the n-well region;
forming a p-type p-base region in the n-well region, including on the base contact region and the emitter region; and
forming a silicide on the source and drain regions, the gate, and the base contact region.

11. The method according to claim 10, wherein the forming of the silicide on the source and drain regions, the gate, and the base contact region comprises:
forming an oxide pattern covering the emitter contact region and the collector contact region;
forming a metal layer on the semiconductor substrate including the oxide pattern;
performing a heat treatment process with respect to the metal layer to silicide the source region, the drain region, the gate, and the base contact region; and
removing unreacted metal of the metal layer after performing the heat treatment process.

12. The method according to claim 11, further comprising removing the oxide pattern.

13. The method according to claim 11, wherein the oxide pattern comprises TEOS.

14. The method according to claim 11, wherein the performing of the heat treatment process is used to activate ions of the source and drain regions, the emitter contact region, the collector contact region, the base contact region, and the p-base region.

15. The method according to claim 10, wherein the silicide is simultaneously formed on the source region, the drain region, the gate, and the base contact region.

16. The method according to claim 10, wherein the p-base region is formed between the emitter contact region and the n-well region such that the p-base region surrounds the emitter contact region in the n-well.

17. The method according to claim 10, wherein the p-base region is formed to a depth deeper than that of the emitter contact region and the base contact region, and shallower than that of the n-well region.

18. The method according to claim 10, wherein forming the source region and the drain region is performed simultaneously with forming the emitter contact region and the collector contact region.

19. The method according to claim 10, further comprising forming a PMOS transistor on the semiconductor substrate, wherein the forming of the base contact region is simultaneously performed with a process of forming a source and drain region for the PMOS transistor.

20. The method according to claim 10, further comprising forming a dielectric on the semiconductor substrate; and
forming contacts through the dielectric to contact the silicided source region, the silicided drain region, the silicided gate, the silicided base contact region, the emitter contact region, and the collector contact region, respectively.
